(19) United States
(12) Patent Application Publication
(10) Pub. No.: US 2024/0349453 A1
(43) Pub. Date: Oct. 17, 2024

(54) METHOD AND APPARATUS FOR A PUMPED LIQUID COOLING SYSTEM USING A PHASE CHANGE REFRIGERANT

(71) Applicant: The Durbin Group, LLC, Fredericksburg, VA (US)

(72) Inventor: Joseph Marsala, Salem, MA (US)

(73) Assignee: The Durbin Group, LLC, Fredericksburg, VA (US)

(21) Appl. No.: 18/299,325

(22) Filed: Apr. 12, 2023

(51) Int. Cl. H05K 7/20

(52) U.S. Cl. CPC H05K 7/20327; H05K 7/20309; H05K 7/20318; H05K 7/20336; H05K 7/20381

(57) ABSTRACT

The present disclosure includes an apparatus for a pumped liquid cooling system using a phase change refrigerant, comprising a rack that can be configured to house a computing tray and house a rack manifold. The rack manifold can include a supply portion, a coupling portion, and a return portion and the computing tray has a cold plate array that has an inlet configured to connect with the coupling portion of the rack manifold, in some cases the cold plate array has a flow regulator and a cold plate configured to connect with the flow regulator and the array can be configured to thermally couple with an electronic component, and connect with an outlet portion that is also configured to couple with the coupling portion.

### TECHNICAL FIELD

The present disclosure relates to the cooling of electronic components and information technology systems.

### BACKGROUND

Integrated electronic device components (such as integrated circuits, microprocessors, semiconductors, etc.), require heat transfer components to minimize inefficiencies caused by increased operating temperature. Processing demands increase the heat generated by such components thereby causing increased electrical resistance within said components. Repeated increased temperature triggered by heavy processing loads can decrease the working lifespan of the components. Similarly, increased temperature and internal resistance of the components reduces functional processing speed which can cause delays in data processing and impose computational limitations.

The present disclosure includes embodiments directed towards cooling electronic components to within a functional operating temperature range.

### SUMMARY

Embodiments of the present disclosure provide cooling to electrical and electronic components with very low parasitic power consumption and very high heat transfer rates away from the component surface through the use of vaporizing refrigerant. Embodiments of the disclosure can also reduce the temperature drop required to move heat from the component to the ambient thermal sink. Further, embodiments of the disclosure include a pumped refrigerant cooling system able to cool rapidly varying loads in multiple locations and can accommodate removal or addition of trays and circuit boards while the system is operating.

The present disclosure includes a pumped liquid cooling system that utilizes a phase change refrigerant. The system can include a rack that can be configured to house both a computing tray and a rack manifold. The rack manifold can include a supply portion, a coupling portion, and a return portion and the computing tray has a cold plate array that has an inlet configured to connect with the coupling portion of the rack manifold, and the array can also have a flow regulator and a cold plate configured to connect with the flow regulator; the array can be configured to thermally couple with an electronic component, and connect with an outlet portion that is also configured to removably couple with the coupling portion. The pumped liquid cooling system can also include a coolant distribution unit that is configured to circulate a phase change coolant to the computing tray via a pump and a controller configured to communicate with the pump and the rack manifold.

Some embodiments of the present disclosure include a multi-phase electronic cooling apparatus that comprises a pump; a first, second and third evaporator; a plurality of thermal interfaces, a chipset, controller, condenser, fluid, and an accompanying piping system designed to transport the fluid. The pump is connected to the first evaporator via the piping system and configured to transmit the fluid therein. The first and second evaporators can be configured to couple with the chipset via the plurality of thermal interfaces. The first and second evaporators have a first and second pressure drop, respectively. The piping system is configured to transport the fluid therein and removably connect the first evaporator to the pump and the second evaporator. The piping system is also configured to removably connect the second evaporator to the third evaporator and the piping system is configured to connect the third evaporator to the manifold. The piping system can also connect the condenser and the pump; wherein the controller is configured to measure the pressure drop between the pump discharge and pump inlet, and control the pump, accordingly, to adjust to a set point.

Embodiments of the present disclosure also include a method of cooling an electronic component. The method of cooling comprises providing a heat generating electronic component, the electronic component is configured to adapt to a removable tray. The removable tray is configured to couple with a rack. Heat generated by the electronic component is transferred to an external portion of a thermal interface. Heat from the external portion of the thermal interface is transferred to a cold plate array. The cold plate array comprises a thermal interface connection configured to couple with the external portion of the thermal interface where the thermal interface connection has an internal cavity. The cold plate array has a piping system configured to couple with a quick connect or dry break, where the piping system and quick connect are configured to transmit a fluid to and from the internal cavity and therein. Heat from the cold plate array is transferred to the fluid. The fluid is transferred through the quick connect to an evaporator, the evaporator comprises a second heating component that is configured to couple to a heat exchanger with an inlet and outlet. The second heating element has an internal cavity and a piping system configured to transport the fluid between the inlet, internal cavity, outlet and therein. The second heating element is configured to communicate with the inlet and the outlet of the heat exchanger. Heat from second heating component is transferred to the heat exchanger. The heat from the heat exchanger is transferred to the fluid. The fluid is compressed and condensed, and the flowrate of the fluid is controlled using a cooling distribution unit. The cooling distribution unit comprises a pump that has a motor, where the pump and motors have speed and pressure sensor configured to communicate with a controller. The pump is configured to pump the fluid to and between the cold plate array and a condenser, and the controller is configured to control the pump motor.

Embodiments include one, more, or any combination of the various apparatus and methods described herein. Other features and advantages of the present disclosure will become apparent from the following more detailed description, taken in conjunction with the accompanying, which illustrate, by way of example, the principles of the disclosure.

### BRIEF DESCRIPTION OF THE DRAWINGS

FIG. 1 illustrates a front elevation perspective view of an electronic component cooling device, according to embodiments of the present disclosure.

FIG. 2 illustrates a top view of an electronic component cooling device, according to embodiments of the present disclosure.

FIG. 3 illustrates a front elevation view of an electronic component cooling device, according to embodiments of the present disclosure.

FIG. 4 illustrates a top view of an electronic component cooling device, according to embodiments of the present disclosure.

FIG. 5 illustrates a front elevation view of an electronic component cooling device, according to embodiments of the present disclosure.

FIG. 6 illustrates a schematic diagram an electronic component cooling device, according to embodiments of the present disclosure.

FIG. 7 illustrates a perspective view of hot swappable pump, according to embodiments of the present disclosure.

FIG. 8 illustrates a pressure vs enthalpy diagram at operational setpoints, according to embodiments of the present disclosure.

FIG. 9 illustrates a pressure vs enthalpy diagram at operational setpoints, according to embodiments of the present disclosure.

Corresponding reference characters indicate corresponding parts throughout the several views.

While the disclosure is amendable to various modifications and alternative forms, specific embodiments have been shown by way of example in the drawings and are described in detail below. The intention, however, is not to limit the disclosure to the particular embodiments described. On the contrary, the disclosure is intended to cover all modifications, equivalents, and alternatives falling within the scope of the disclosure as defined by the appended claims.

### DETAILED DESCRIPTION

The following detailed description illustrates embodiments of the disclosure and manners by which they can be implemented. Although the best mode of carrying out the present disclosure has been disclosed, those skilled in the art would recognize that other embodiments for carrying out or practicing the present disclosure are also possible.

It should be noted that the terms “first,” “second,” and the like, herein do not denote any order, quantity, or importance, but rather are used to distinguish one element from another. Further, the terms “a” and “an” herein do not denote a limitation of quantity, but rather denote the presence of at least one of the referenced item.

Electrical and electronic components (e.g., CPU's, GPU's. XPU's, microprocessors, IGBT's, power semiconductors etc.) are most often cooled by air-cooled heat sinks with extended surfaces, directly attached to the surface to be cooled. In this manner a fan or blower moves air across the heat sink fins removing the heat generated by the component. With increasing power densities, miniaturization of components and shrinking of packaging it is sometimes not possible to adequately cool electrical and electronic components with heat sinks and forced air flows. When this occurs, other methods must be employed to remove heat from the components.

Some embodiments of the present disclosure provide a method and apparatus for a pumped liquid cooling system using a phase change refrigerant. A refrigerant such as R-134a, R-1234yf or R-515b may be used as well as many other refrigerants known to those skilled in the art. The refrigerant is then at least partially vaporized by the heat generated by the component. The vapor is condensed to a liquid by a conventional condenser coil or heat exchanger (either air or secondary fluid) and the condensed fluid along with any remainder of non-vaporized liquid is returned to the pump. The system can account for widely varying pressure drops when changes to dissipated loads occur or when trays and boards are added or removed from the rack system, via the implementation of flow regulators and controllers, thus compensating for varying loads and the addition or removal of hardware or trays to a computing rack that implements various embodiments of the present disclosure.

Some embodiments of the present enclosure include a system capable of cooling a computing system or server rack with trays containing heat dissipating components that changes from idle power to burst full power in as little as several micro-seconds. In some cases, the disclosed system can handle full thermal design power for at least 1 kilowatt devices, or 8 kilowatts per tray or higher. It is contemplated that embodiments of the disclosed systems and methods can be configured to properly cool a computing system down to chip manufacturer thermal specifications, wherein that computing system generates hundreds of kilowatts of heat due to computing demands.

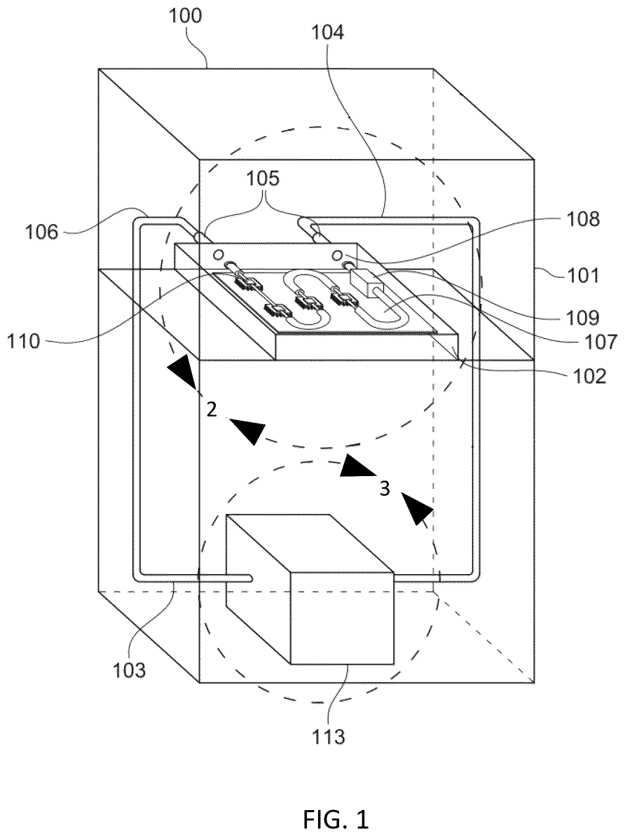

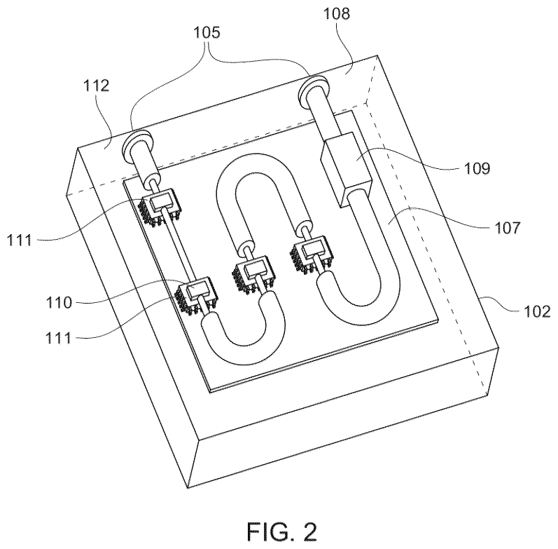

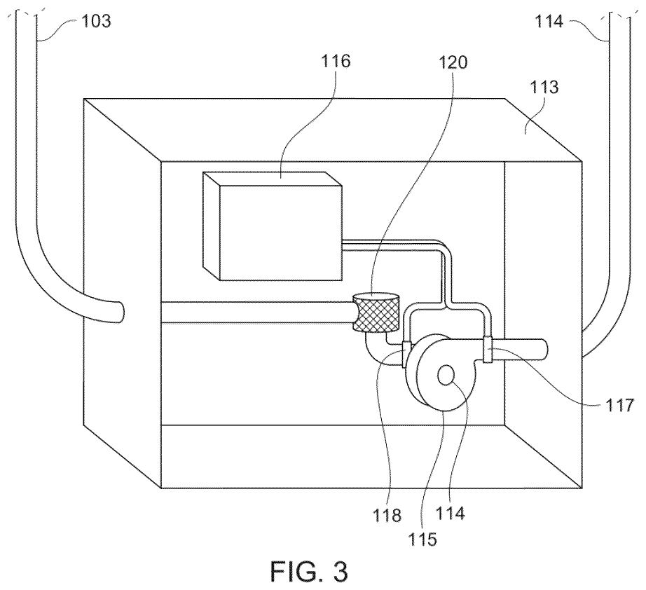

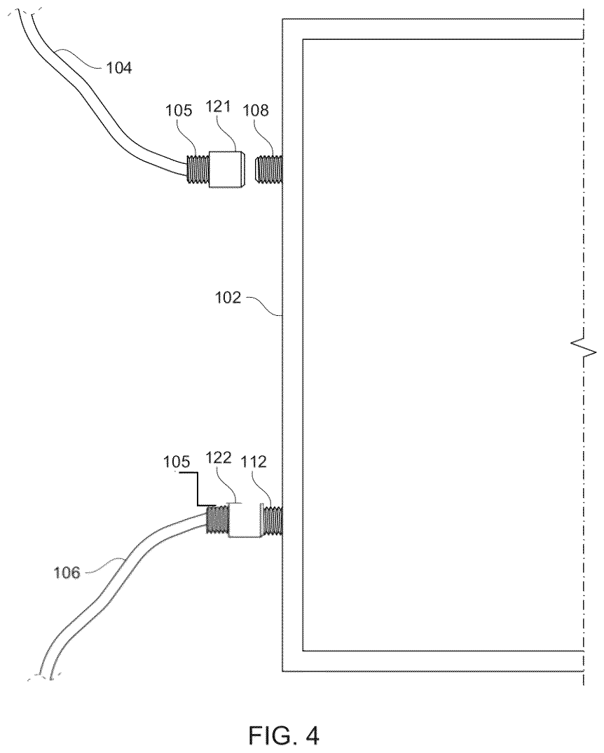

As shown in FIGS. 1, 2, 3, and 4, according to embodiments of the present disclosure a system 100 for controlling operating temperature of electronic components via phase change liquid cooling comprises a rack 101 configured to house at least one computing tray 102, and a rack manifold 103 is provided. The term “rack” includes, but is not limited to; server rack, computing rack, server cabinet, 19-inch rack, or a standardized frame or enclosure that includes multiple electronic equipment modules, and that can be used for computer servers, telecommunications equipment, networking hardware, and scientific instrumentation equipment. The term “computing tray” includes but is not limited to; a computing module configured to adjustably and removably connect in a modular fashion with a server rack, cabinet, or other rack system, and the removable connection can be accomplished with fasteners, rails, or frictional device implementation.

In some embodiments, the rack manifold 103 has a supply portion 104, a coupling portion 105, and a return portion 106; where the manifold system is configured to accommodate a plurality of computing trays, modules, and other electronic components that require temperature stabilization. In some cases, the computing tray 102 has a cold plate array 107 that is configured to align with a printed computer board, processors, or other computing module. The cold plate array 107 has an inlet 108 configured to connect with the coupling portion 105 of the rack manifold 103, and a flow regulator 109 in some cases. The flow regulator 109 can be configured to respond to pressure differences in a flow network within the system 100 and the flow regulator 109 can be operable across a range of pressures (e.g., between 2-150 pounds per square inch (PSI)) at a constant flow rate. Flow regulators can be, but are not limited to, piston and spring type flow regulators, flexible metal orifice, cone type, or elastomeric variable-orifices responsive to pressure difference.

The cold plate array 107 has at least one cold plate 110 configured to connect with the flow regulator 109 and the cold plate 110 has a heat transfer surface configured to thermally couple with an electronic component 111. The heat transfer surface is configured to enable heat transfer between the electronic component 111 and the cold plate 110. The cold plates 110 are designed to maximize surface area, minimize pressure drop, and maximize fin efficiency. The electronic component 111 can be, but is not limited to, a heat generating component of a computing module, such as a processing unit. The coupling portion 105 of the rack manifold 103 is configurable to connect with an outlet 112 of the cold plate array 107.

In some embodiments, the system also includes a coolant distribution unit (CDU) 113 that is configurable to circulate a vaporizable refrigerant coolant 114 to the computing tray via a pump 115, a controller 116, and the rack manifold 103. The CDU 113 can be configured to be housed within the rack 101, or in some cases in a separate location. The pump can be, but is not limited to, a positive displacement design or a regenerative turbine design. The CDU 113 is configurable to be housed between a plurality of rack manifolds 103 within a single rack 101, in some cases.

In some embodiments, the flow regulator 109 is configured to deliver the coolant 114 at a flow rate as determined by a thermal design power (TDP). The TDP can be determined by the maximum amount of heat generated by the electronic component 111 as typically determined by the manufacturer of the electronic component. In some cases, the TDP can be a scenario design power, which accounts for removal and addition of a plurality of computing trays 102 to the rack 101. In cases where a plurality of computing trays 102 are present in the rack 101, the refrigerant flow rate is set in conjunction with the flow regulators to ensure that the coolant 114 does not undergo complete vaporization in the cold plate 110 when the devices operate at TDP.

In some cases, the coolant 114 comprises a liquid phase, a vapor-liquid equilibrium phase, and an enthalpy of vaporization wherein the regulator 109 specification is determined the TDP and enthalpy of vaporization of the coolant. The coolant 114 can be selected in accordance with the TDP, system 100 size, length of rack manifold 103 piping and thermal properties, and number of cold plate arrays 107 such that the coolant 114 flow rate is set such that typically less than 80% of complete vaporization of the coolant 114 occurs.

In some embodiments, the system 100 includes a plurality of computing trays 102 such that each computing tray 102 is configured to be removable from the rack 101 without disassembly of the entire system 100. Removability can be accomplished via hot-swappable computer trays 102, in which the coolant 114 does not need to be removed from the system 100, nor the CDU 113 powered-off to enable the addition or removal of the various computing trays 102, in some cases.

In some embodiments, the system 100 can further include a pump inlet 117, pump outlet 118, and a motor 119. The system 100 can also include at least one pressure sensor 120 configured to couple with the pump 115 and communicate with the CDU 113. The pressure sensor 120 can be a transducer configured to convert the measured pressure into a transmittable signal. Wherein the controller 116 is configured to communicate 121 with the pressure sensor 120, pump inlet 117, pump outlet 118, and the motor 119 to determine a pump setpoint, in some cases. In some embodiments, the pump setpoint is further determined by the number of computing trays 102 in the rack, in which the controller 116 adjusts the pump setpoint based on the inferred number of computer trays 102 in the rack 101 based on the differential pressure across the pump inlet and discharge.

According to some embodiments of the disclosure, the system 100 includes a first multiphase quick connect 121 and a second multiphase quick connect 122, in which the first multiphase quick connect 121 is configured to adapt to the manifold coupling portion 105 and the cold plate array inlet 108, and the second multiphase quick connect 122 is configured to couple to the manifold coupling portion 105 and the cold plate array outlet 112. The first and second multiphase quick connects 121 122, can be, but are not limited to, a tooled dry break, quick connect dry break, or a blind mate dry break.

In some cases, the second multiphase quick connect 122 comprises a first position and a second position; wherein the first position of the second multiphase quick connect 122 is configured to transport the coolant 114 between the cold plate array outlet 112 and the manifold coupling portion 105, and the second position of the second multiphase quick connect 122 is configured to stop transport the coolant 114 between the cold plate array outlet 112 and the manifold coupling portion 105, wherein the coolant 114 comprises a multi-phase fluid with an equilibrium between least two phases during operational parameters of the system 100, according to some embodiments.

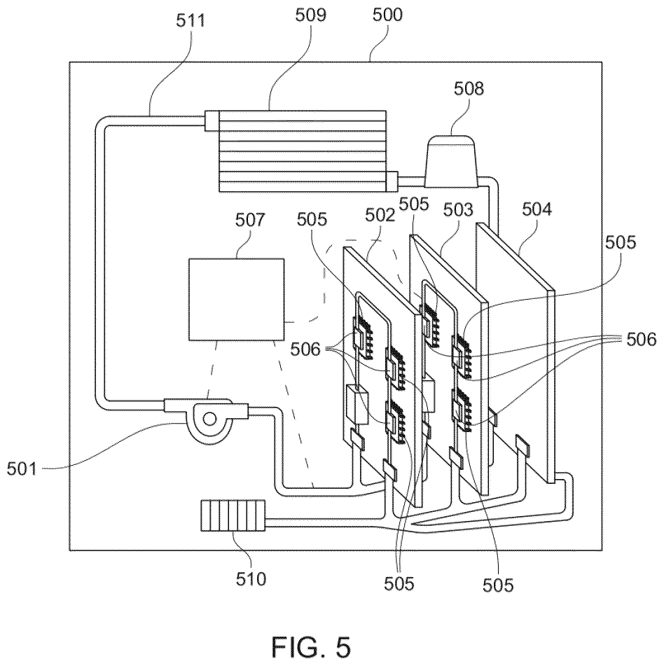

As shown in FIG. 5, in some embodiments of the present disclosure, a multi-phase electronic cooling apparatus 500 comprises a pump 501, a first evaporator 502, a second evaporator 503, a third evaporator 504, a plurality of thermal interfaces 505, a chipset 506, a controller 507, a condenser 509, a fluid, and a piping system 511 wherein the pump 501 is connected to the first evaporator 502 via the piping system 511, and the pump 501 is configured to pump the fluid throughout the piping system 511. The first 502 and second 503 evaporators can be configured to couple with the chipset 506 via the plurality of thermal interfaces 505, in which the first and second evaporators 502 503 have a first and second pressure drop, respectively.

In some cases, the piping system 511 is configured to transport the fluid in a fashion that accommodates for removable connections of the first evaporator 502 to the pump 501 and the second evaporator 503. The piping system 511 can further accommodate removably connecting the second evaporator 503 to the third evaporator. The piping system 511 connects the condenser 509 and the pump 501, in which the controller 507 is configured to measure the pressure drop of the first and second evaporators 502 503 and control the pump 501, according to some embodiments.

In some cases, the apparatus 500 includes a fluid that has a first state, a second state, and a third state; wherein the fluid is in the first state in the piping system 511 between the condenser 509 and the pump 501, a second state in the piping system 511 between the first evaporator 502 and the second evaporator 503, and in a third state in the piping system 511 between the third evaporator 504 and the condenser 509. According to some embodiments, the first state of the fluid is single phase in the liquid form, the second state of the fluid is a two-phase equilibrium, and the third state of the fluid is a two-phase equilibrium at an operator determined percentage.

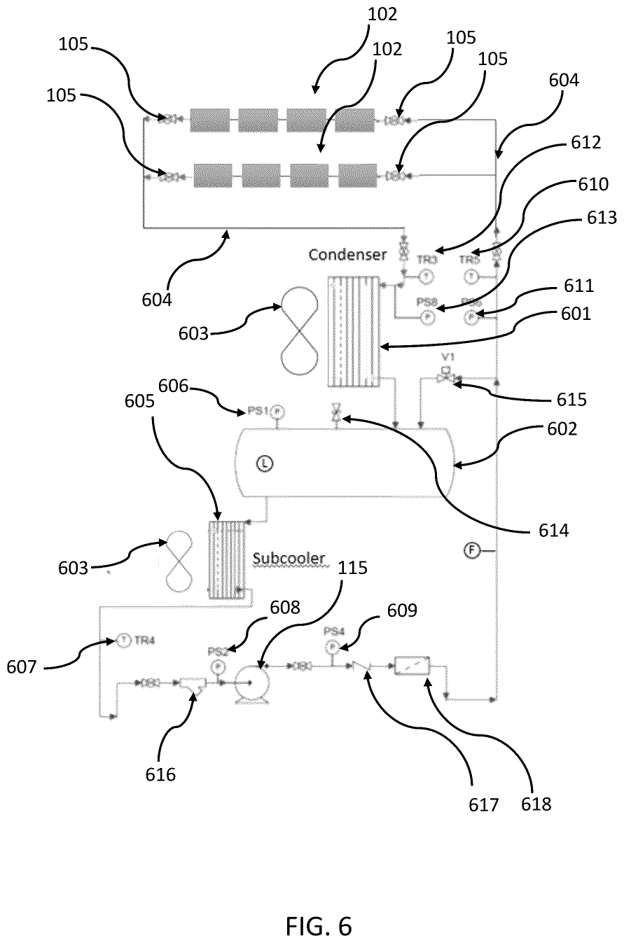

As shown in FIGS. 1, 2, 3, 4, and 6 in some cases, the CDU 113 provides the coolant 114 to each cold plate 110 and then dissipates the thermal load, removes via the coolant 114 from each cold plate 110, to ambient atmosphere via a condenser coil 601. The condenser coil 601 is located at the top of the CDU 113 and is oriented for gravity drain to increase efficiency. At least one pump 115 can used to provide the flow and pressure required by the system 100 to cool 6.4 KW generated by the electronic components 111. Coolant 114 that has traveled through the condenser coil 601 can be stored in the reservoir 602 which can be located in the CDU 113. In some cases, the reservoir 602 comprises and pressure relief valve 614, and a bypass valve 615 configured to connect to the supply portion 104 to accommodate diminished pumping flowrate outside the at least one pump 115 acceptable operating parameters.

According to some embodiments of the present disclosure, a fan 603 can be included to force air over the condenser coil 601 and other components. In some cases, the fan 603 can be hot swappable, with N+1 fans 603 being utilized in various embodiments. The CDU 113 operating under a saturation temperature setpoint will automatically increase the fan 603 speeds to compensate for a failed fan until it is replaced. Once the failed fan is replaced the CDU 113 will decrease fan 603 speed to maintain the proper saturation temperature. Notification of this failure can be reported across a wireless network so an operator is aware of the fault condition and can take appropriate action to replace the failed component via system shutdown, or “hot-swap” the fan 603 component.

The condenser coil 601 performance in the CDU 113 establishes the saturation temperature for the entire pumped coolant loop 604. The boiling point in each cold plate 110 computing trays 102 is equal to the condenser coil 601 saturation temperature adjusted for a small amount of pressure drop for the entire pumped coolant loop 604. Heat addition in the cold plate 110 and rejection in the condenser coil 601 is isothermal, thus the condenser design is of critical importance. For an air-cooled condenser, the air inlet temperature, air volumetric flow rate and face area are the three parameters which dictate performance. Present air-cooled condensers used in HVAC/R applications have migrated to aluminum microchannel extrusions to optimize refrigerant side heat transfer coefficients and minimize weight and refrigerant charge when compared to traditional copper tube aluminum fin condensers. Coil orientation of the condenser coil 601 can be optimized to be between a range of 20-40 degrees. Additionally, the condenser coil 601 can include expansion valves and/or pressure release valves to regulate variations in operation setpoints.

The rack manifold 103 circulates coolant 114 from the reservoir 602 in the CDU 113, to the server tray cold plates 110 that cool the electronic components 111, and then back to the condenser coil 601. To reduce the risk of pump 115 cavitation, a sub-cooler 605 can be included after the reservoir 602 to ensure the net positive suction head required for the pump 115. Due to use of pump 115 the CDU 113 operates above ambient temperature.

CDU 113 Operation: The operation of the CDU 113 requires minimal input from the operator. The system automatically adjusts fan speed based on desired saturation temperature setpoint and pump 115 speed can be controlled by differential pressure or desired flow rate. Once the operating parameters are set the system will self-balance based on load and ambient air temperatures to maintain the desired electronic component 111 temperature.

All health parameters of the CDU 113 are available on the network and the user can monitor N number of CDU 113s simultaneously with early warnings of component failures to enhance preventive maintenance. The CDU 113 monitors and provided feedback on the network for the following: Ambient temperature, Saturation set point, Condenser inlet temperature/pressure, Reservoir pressure measure via a reservoir pressure sensor 606, subcooler exit temperature measured by subcooler temperature probe 607, Pump 115 speed, Coolant 114 flow rate, pump inlet 117 pressure measure by pump inlet pressure sensor 608, pump outlet 118 temperature/pressure measured by pump outlet probe 609, Fan 603 PWM, Pump 115 fault, Fan fault, Power supply fault, Coolant 114 level, small sensor elements exist which are used to detect refrigerant leaks in concentrations as low as 10 ppm. The pump 115 assembly can also have a strainer 616, a check valve 617, and a filter 618 to remove floc or solute in suspension. Additionally, according to some embodiments, the supply portion 104 has a supply temperature sensor 610 and supply pressure sensor 611; the return portion 106 can also have has a return temperature sensor 612 and return pressure sensor 613.

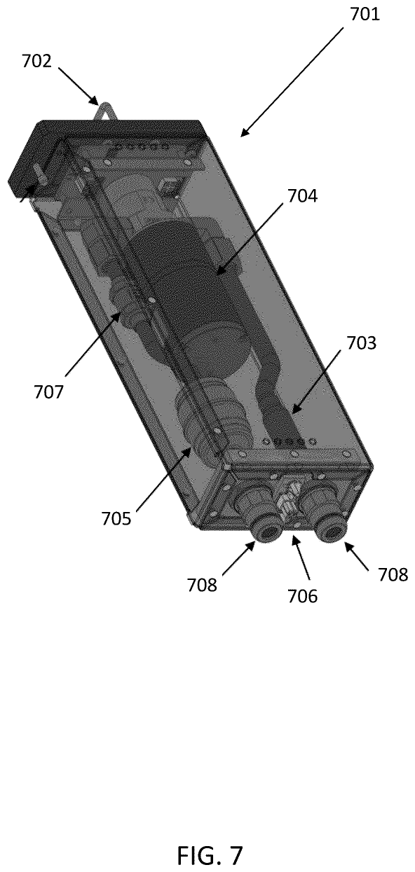

As shown in FIG. 7 some embodiments of the present disclosure include a hot swappable pump assembly 701. To replace a hot swappable pump assembly 701 an operator removes the screw holding the assembly in place and slides the unit out of the CDU 113 chassis via the handle 702. The system will continue to operate throughout the operation. Once a new pump 115 assembly is slid into place the system will provide power and the replaced pump 115 will become operational. Each hot swappable pump assembly 701 can contain a strainer 703, geroter pump 704, filter/dryer 705, power connector 706, a check valve 707, and multiphase pump quick connect 708. The multiphase pump quick connects 708 are configured to seal and then open of the system for flow and can be, but are not limited to, a tooled dry break, quick connect dry break, or a blind mate dry break. The hot swappable pump assembly 701 can be pre-charged with coolant 114 and ready for install in the event of a pump 115 fault.

According to some embodiments of the present disclosure, a method of cooling an electronic component, comprises providing a heat generating electronic component 800 to be cooled. The heat generating component can be, but is not limited to, a heat generating component of a computing module, such as a processing unit. The electronic component can be configured to adapt to a removable tray being that is further configured to couple with a rack.

In some cases, the method of cooling an electronic component includes transferring the heat generated by the electronic component to an external portion of a thermal interface, transferring the heat from the external portion to a cold plate array, the cold plate array includes a thermal interface connection that is designed to interface with the external portion of the thermal interface. In some cases, the thermal interface connection phase has an internal cavity. A piping system is also provided to couple with a quick connect and transmit a fluid to and from the internal cavity of the thermal interface connection.

According to some embodiments, the method of cooling an electronic component includes transferring the heat from the cold plate array to the fluid, via conductive and convective heat transfer as the fluid interfaces with the surfaces of the cold plate array. In some cases, the heat transferred from the cold plate array to the fluid vaporizes the fluid. The fluid can be transmitted through the quick connect to an evaporator, i.e. cold plate, comprising a second heating component configured to couple to a heat exchanger with an inlet and outlet. The evaporator can also be designed to include an internal cavity and a piping system configured to transport the fluid within the evaporator and between the inlet, internal cavity, and outlet.

According to some embodiments, the method of cooling an electronic component includes transferring the heat from second heating component to the heat exchanger and can include transferring the heat from the heat exchanger to the fluid. The method can also include compressing the fluid by way of temperature control, condensing the fluid, controlling the flowrate of the fluid using a cooling distribution unit, in some cases. The cooling distribution unit comprises a pump that includes a motor with a speed and a pressure sensor each configured to communicate with a controller. In some cases, the pump is configured to pump the fluid between the cold plate array, the heat exchanger, and a condenser, and the controller is configured to control the motor the motor speed based on pressure sensor communications with the controller.

The method of cooling an electronic component can in some cases include transferring the heat from the cold plate array to the fluid. Transferring the heat from the cold plate array to the fluid can include absorbing the heat in the cold plate array into the fluid and vaporizing a portion of the fluid within the cold plate array in an isothermal process. In some cases, transferring the heat from the heat exchanger to the fluid comprises absorbing the heat in the heat in the heat exchanger into the fluid; vaporizing all the fluid within the heat exchanger and adjusting the flow of the fluid at the inlet of the heat exchanger relative to the heat transferred at the outlet, according to some embodiments.

The method of cooling an electronic component of may further comprise transferring the heat generated by a second electronic component to an external portion of a second thermal interface and transferring the heat from the external portion of the second thermal interface to a second cold plate array, according to some embodiments. In some cases, the second cold plate array comprises a second thermal interface connection that is configured to couple with the external portion of the second thermal interface and the second thermal interface connection comprises a second internal cavity and a second piping system configured to couple with a second quick connect and transmit the fluid to and from the second internal cavity and is operable to transfer the heat from the second cold plate array to the fluid.

According to some embodiments, the method of cooling an electronic component includes hot-swapping-out the second cold plate array. Hot-swapping-out the second cold plate array comprises disconnecting the second quick connect which is operable to stop the transmission of the fluid within the second piping system and includes adjusting the motor speed via the controller and the pressure sensor, in some cases.

In some cases, the method of cooling an electronic component includes adjusting the motor speed of the pump proportional to pressure changes sensed by the pressure sensor and the required fluid flow rate to achieve partial vaporization in the cold plate array, and complete vaporization in the heat exchanger, as determined by a proportional gain. According to some embodiments, the motor speed of the pump can also be adjusted based on the pressure sensor communications to the controller as a function of the vaporization needs at the cold plate array and the heat exchanger over time that the pump motor operates, where the pressure is sensed by the pump pressure sensor and the controller measures the pressure over a period of time and adjusts the motor speed on by an integral of the pressure sensor measurements. In comes cases, the pump motor speed is adjusted by the controller based on proportional rate of change of the pressure sensor measurements of the pump.

According to some embodiments, the method of cooling an electronic component of comprises regulating the flow of the fluid to the cold plate array via a flow regulator configured to connect between the quick connect and the piping system.

In some cases, the method of cooling an electronic component comprises hot-swapping-in the second cold plate array which includes connecting second quick connect and starting the transmission of the fluid within the second piping system. Hot-swapping-in further includes adjusting the motor speed via the controller and the pressure sensor, regulating the flow of the fluid to the cold plate array via a flow regulator that is configured to connect between the quick connect and the piping system, and regulating the flow of the fluid to the second cold plate array via a second flow regulator that is configured to connect between the second quick connect and the second piping system, according to some embodiments.

According to some embodiments, the method of cooling an electronic component further includes maintaining a flowrate across the flow regulator despite a pressure differential of 0-20 PSI, as measured from the upstream side of the flow regulator. The flow regulator can be configured to accommodate a flow rate of 10 gallons per minute (GPM) and full dissipation of a 20 PSI pressure differential.

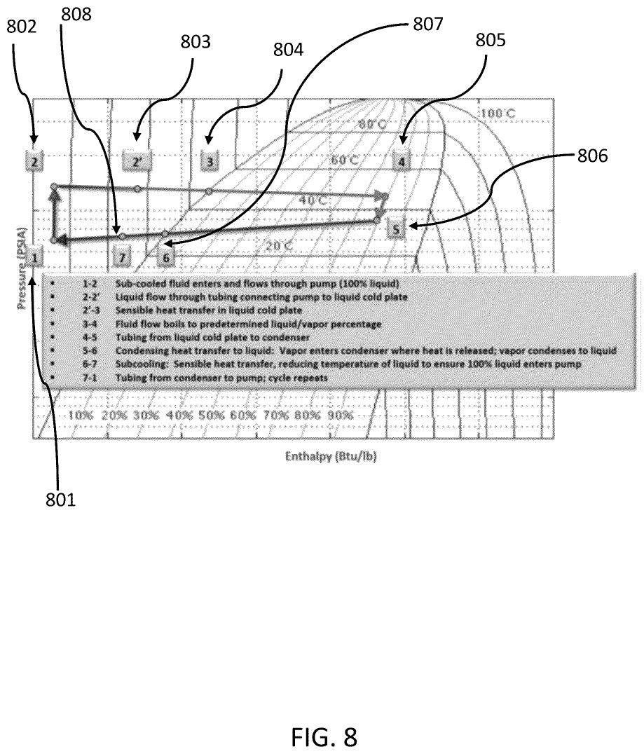

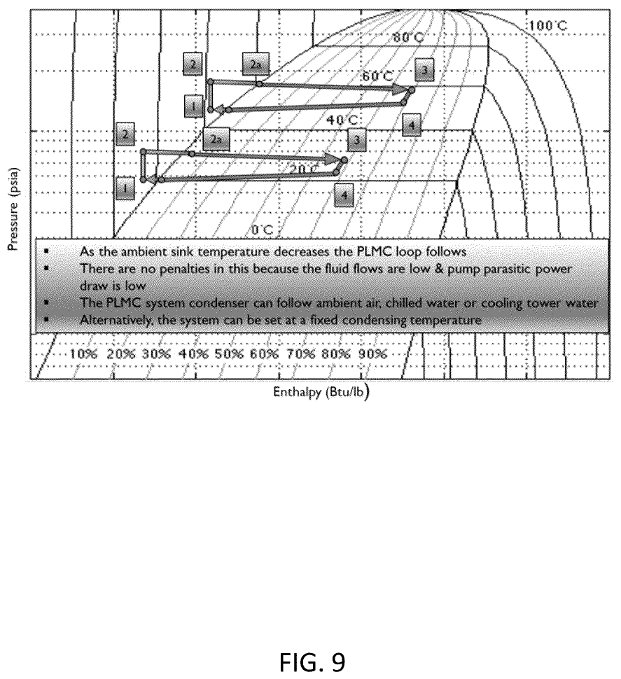

As shown in FIG. 8 and FIG. 9 different operating points can be employed to run the system 100 across all load cases, such as, but not limited to constant saturation temperature, or constant fan speed. Constant saturation temperature control method modulates the fan speeds such that the fans will increase or decrease speed to maintain the same user-selected saturation temperature setpoint regardless of thermal load and ambient temperature. The constant saturation temperature control method provides the electronic components are at the same temperature at all operating conditions. The constant fan speed method provides the saturation temperature to rise and fall with ambient temperature and thermal load, while maintaining a user-selected fan speed setpoint value. As the thermal load increases and ambient increases so does the saturation temperature. This increase will reach steady state at max ambient and max thermal load design point.

As shown in FIGS. 1, 2, and 8 when under constant saturation temperature control, the coolant 114 at 801 flows from the subcooler 605 to the pump 115 and is pumped 802 to the supply portion 104 nearly isoenthalpically. As the coolant 114 flows from the supply portion 104 to the cold plate array 107 via the pressure regulator 109 the pressure regulator 109 is configured to maintain a constant flow rate by increasing or decreasing pressure 803. As the coolant 114 flows through the cold plate 110 and the latent and sensible heat from the electronic component 111 is absorbed 804 by the coolant 114 via the surface area of the cold plate 110 where the latent heat of the electronic component 111 causes a partial phase change 804 in the coolant 114. As the coolant 114 passes through the cold plates 110 in the cold plate array 107 the coolant 114 boils to an operational setpoint of liquid/vapor percentage 805. The coolant 114 travels from the computing tray 102 through the return portion 106 undergoing nearly isenthalpic expansion via adiabatic cooling 806 before the coolant 114 enters the condenser coil 601. While the coolant 114 flows into the condenser coil 601 the coolant 114 condenses at least partially 807 before traveling to the subcooler 605 where at least sensible heat transfer, and in some cases latent heat transfer, occurs 808 ensuring the coolant 114 is 100% liquid phase for pump 115 operation, and return of the coolant 114 to the supply portion 104.

The CDU 113 is configured to be adaptable to multiple tray installs and varying operating conditions. The system can be pre-charged and shipped either in individual modules or as an integrated system. Each component can also be shipped individually for maximum flexibility and reliability. The unboxing procedures can be as follows: Unpacking the rack which includes the supply and return manifold, unboxing the CDU 113 and remove shipping packaging. Unboxing server trays and remove shipping packaging, unboxing tray support equipment and remove shipping packaging, removing all coupling caps for trays, CDU 113, and manifolds, and visually inspecting ports and connections and ensuring they are in good working order. With appropriate lifting aids, the next step is sliding the system into the rack and ensuring it is supported by appropriate bracketry which may also include fastening the system to the rack frame using the mounting holes. With appropriate lifting aids sliding the servers and supporting equipment into the rack, the next steps are: ensuring the trays are supported by appropriate bracketry, ensuring the refrigerant cooled trays align with the manifold port locations, connecting the servers supply and return ports to the manifold hoses using single hand tooling, connecting the CDU 113 to the supply and return ports using single hand tooling, ensuring the front switch on the CDU 113 is in the “off” position, plugging the CDU 113 into wall power, connecting network cable to operating tablet or network, checking connections for leaks, rotating the front switch to “Run,” setting the temperature saturation setpoint, setting the constant fan speed setpoint, ensuring no system faults, monitoring and controlling system parameters from the user interface, and then stopping the operation by rotating the front switch to “Off.”

The examples mentioned above are merely used for illustrative purposes and not meant to be limitations of the present disclosure. Furthermore, the approaches in various embodiments of the present disclosure are implemented according to the universal conversion method and related circuitry provided by the embodiments of the present disclosure.

What is claimed is:

1. A system for cooling electronic components, comprising:
a rack configured to house at least one computing tray and a rack manifold comprising a supply portion, a coupling portion, and a return portion wherein the computing tray has a cold plate array comprising an inlet configured to connect with the coupling portion and a flow regulator, a cold plate configured to connect with the flow regulator, thermally couple with an electronic component, and to connect with an outlet portion configured to couple with the coupling portion;
a coolant distribution unit configured to circulate a coolant to the computing tray via a pump, a controller, and the rack manifold.

2. The system of claim 1, wherein the flow regulator is configured to deliver the coolant at a flow rate as determined by a thermal design power.

3. The system of claim 2, wherein the coolant comprises a liquid phase, a two-phase equilibrium, and an enthalpy of vaporization wherein the flow rate is determined the thermal design power and enthalpy of vaporization of the coolant.

4. The system of claim 1, further comprising:
a plurality of computing trays, wherein each computing tray is configured to be removable from the rack.

5. The system of claim 4, further comprising:
a pump inlet, pump outlet, and a motor; and
At least one pressure sensor configured to couple with the pump and communicate with the coolant distribution unit, wherein the controller is configured to communicate with the pressure sensor, pump inlet, pump outlet, and the motor to determine a pump setpoint.

6. The system of claim 5, wherein the pump setpoint is further determined by an operation setpoint.

7. The system of claim 6, wherein the flow regulator is configured to accommodate a pressure change of 20 PSI.

8. The system of claim 4, further comprising:
a first multiphase quick connect and a second multiphase quick connect;
wherein the first multiphase quick connect is configured to adapt to the manifold coupling portion and the cold plate array inlet, and the second multiphase quick connect is configured to couple to the manifold coupling portion and the cold plate array outlet.

9. The system of claim 8, wherein the second multiphase quick connect comprises a first position and a second position;
wherein a first position of the second multiphase quick connect is configured to transport the coolant between the cold plate array outlet and the manifold, and a second position of the second multiphase quick connect is configured to stop transport the coolant between the cold plate array outlet and the manifold, wherein the coolant comprises a multi-phase fluid at equilibrium between at least two phases.

10. A multi-phase electronic cooling apparatus comprising:
a pump,
a first evaporator,
a second evaporator,
a third evaporator,
a plurality of thermal interfaces,
a chipset,
a controller,
a condenser,
a fluid,
a piping system; and
wherein the pump is connected to, configured to transmit the fluid between, the first evaporator via the piping system, the first and second evaporators being configured to couple with the chipset via the plurality of thermal interfaces having a first and second pressure drop, respectively; the piping system is configured to transport the fluid therein and removably connect the first evaporator to the pump and the second evaporator, removably connect the second evaporator to the third evaporator, connect the third evaporator to the condenser and the pump;
wherein the controller is configured to measure the pressure drop of the first and second evaporators and control the pump.

11. The apparatus of claim 10 wherein the fluid comprises a first state, a second state, and a third state; wherein the fluid is in the first state in the piping system between the condenser and the pump, a second state in the piping system between the first evaporator and the second evaporator, and in a third state in the piping system between the third evaporator and the condenser.

12. A method of cooling an electronic component, comprising:
providing a heat generating electronic component, the electronic component being configured to adapt to a removable tray being configured to couple with a rack;
transferring the heat generated by the electronic component to an external portion of a thermal interface;
transferring the heat from the external portion to a cold plate array, the cold plate array comprising:
a thermal interface connection configured to couple with the external portion of the thermal interface, the thermal interface connection providing an internal cavity, a piping system configured to couple with a quick connect and transmit a fluid into and from the internal cavity;
transferring the heat from the cold plate array to the fluid;
transmitting the fluid through the quick connect to an evaporator, the evaporator comprising:
a second heating component configured to couple to a heat exchanger with an inlet and outlet, an internal cavity and a piping system configured to transport the fluid between and into the inlet, internal cavity, and outlet;
transferring the heat from second heating component to the heat exchanger;
transferring the heat from the heat exchanger to the fluid;
compressing the fluid;
condensing the fluid;
controlling a flowrate of the fluid using a cooling distribution unit, the cooling distribution unit comprising:
a pump comprising:
a motor having a speed and a pressure sensor configured to communicate with a controller;
wherein the pump is configured to pump the fluid between the cold plate array, the heat exchanger, and a condenser;
wherein the controller is configured to control the motor.

13. The method of claim 12, wherein transferring the heat from the cold plate array to the fluid comprises:
absorbing the heat in the cold plate array into the fluid;
vaporizing a portion of the fluid within the cold plate array in an isothermal process.

14. The method of claim 13, wherein transferring the heat from the heat exchanger to the fluid comprises:
absorbing the heat in the heat in the heat exchanger into the fluid;
vaporizing a percentage of the fluid within the heat exchanger;
transferring heat at the outlet of the heat exchanger to the fluid;
adjusting the flowrate of the fluid at the inlet of the heat exchanger relative to the heat transferred at the outlet.

15. The method of claim 14, further comprising:
transferring the heat generated by a second electronic component to an external portion of a second thermal interface;
transferring the heat from the external portion of the second thermal interface to a second cold plate array, the second cold plate array comprising:
a second thermal interface connection configured to couple with the external portion of the second thermal interface, the second thermal interface connection comprising:
a second internal cavity, a second piping system configured to couple with a second quick connect and transmit the fluid to and within from the second internal cavity; and
transferring the heat from the second cold plate array to the fluid.

16. The method of claim 15, further comprising:
hot-swapping-out the second cold plate array, comprising:
disconnecting the second quick connect, comprising:
stopping the transport of the fluid within the second piping system; and
adjusting the motor speed via the controller and the pressure sensor.

17. The method of claim 16, wherein adjusting the motor speed comprises:
decreasing the motor speed proportional to pressure changes sensed by the pressure sensor.

18. The method of claim 16, further comprising:
regulating the flowrate of the fluid to the cold plate array via a flow regulator configured to connect between the quick connect and the piping system.

19. The method of claim 16, further comprising:
Hot-swapping-in the second cold plate array, comprising:
connecting the second quick connect, comprising:
transmitting of the fluid within the second piping system;
adjusting the motor speed via the controller and the pressure sensor;
regulating the flowrate of the fluid to the cold plate array via a flow regulator configured to connect between the quick connect and the piping system; and
regulating the flow of the fluid to the second cold plate array via a second flow regulator configured to connect between the second quick connect and the second piping system.

20. The method of claim 19, wherein the flow regulator is configured to accommodate a pressure differential of 0-20 PSI, comprising:
dissipation of pressure differential across the flow regulator as measured on an upstream side of the flow regulator, and
maintaining flow across the flow regulator at up to 10 GPM.
